(19) United States
(12) Patent Application Publication
(10) Pub. No.: US 2013/0120947 A1
(43) Pub. Date: May 16, 2013

(54) ELECTRICAL DEVICE WITH CONNECTION INTERFACE, CIRCUIT BOARD THEREOF, AND METHOD FOR MANUFACTURING THE SAME

(71) Applicant: Dawning Leading Technology Inc., Miao-Li (TW)

(72) Inventor: Diann-Fang LIN, Miao-Li (TW)

(73) Assignee: DAWNING LEADING TECHNOLOGY INC., Miao-Li (TW)

(21) Appl. No.: 13/678,898

(22) Filed: Nov. 16, 2012

(30) Foreign Application Priority Data
Nov. 16, 2011 (TW) 100141895

(51) Int. Cl. H05K 7/06; H05K 3/30; H05K 1/11

(52) U.S. Cl. CPC H05K 7/06; H05K 1/111; H05K 3/303; H05K 3/305; H05K 3/306
USPC 361/767; 174/261; 29/832; 29/852

(57) ABSTRACT

The present invention discloses an electrical device with a connection interface, a circuit board thereof, and a method for manufacturing the same. The electrical device with a connection interface includes: a circuit board on which a first circuit layer and a second circuit layer are formed and the second circuit layer has plural terminal pads, wherein a cavity is formed in the terminal pads and extends to the first circuit layer, and a metal layer is disposed in the cavity and connected to the first circuit layer and the terminal pads and defines an opening; a semiconductor chip electrically connected to the first circuit layer; and a conductive element interlaid in the opening. The electrical device with a connection interface does not need to be formed by assembling a terminal module because the conductive element is directly mounted on the circuit board.

### CROSS REFERENCE TO RELATED APPLICATION

This application claims the benefits of the Taiwan Patent Application Serial Number 100141895, filed on Nov. 16, 2011, the subject matter of which is incorporated herein by reference.

### BACKGROUND OF THE INVENTION

1. Field of the Invention

The present invention relates to an electrical device, a circuit board thereof and methods for manufacturing the same and, more particularly, to an electrical device with a connection interface, a circuit board thereof and methods for manufacturing the same.

2. Description of Related Art

As the development of portable electronic devices, electronic cards or other electronic systems, the specifications of connection interfaces are also changed. For example, the specifications of Universal Serial Bus (USB) is developed from the original USB 1.0 to USB 2.0, and further moved to USB 3.0 used nowadays; and the development of USB is gradually moved on.

Conventional connection interfaces can be referred to Taiwan Utility Model Patent M413989 issued on Oct. 11, 2011, which disclose a connection interface with terminal modules. The disclosed connection interface comprise a circuit board and a terminal module, wherein the circuit board and the terminal module of the connection interface are fabricated individually, and then conductive sheets and elastic terminals are laminated on the circuit board to electrically connect to each other. After the aforementioned process, a connection interface can be obtained.

The conventional elastic terminals are generally disposed in the terminal module, and then the terminal module is laminated and assembled on the circuit board to obtain the purpose of electrically connecting the terminal module to the circuit board. Since the elastic terminals are not assembled on the circuit board directly, additional assembling process of the terminal module has to be performed. Therefore, the assembling process and the manufacturing cost are increased.

### SUMMARY OF THE INVENTION

An object of the present invention is to provide an electrical device with a connection interface, wherein an opening is formed on a circuit board. Hence, a conductive element can be interposed on the circuit board directly without using additional mounting terminal modules. Therefore, the assembly process can be simplified and the process reliability can further be improved.

To achieve this object, an aspect of the present invention provides an electrical device with a connection interface, which comprises: a circuit board, a semiconductor chip and a conductive element. The circuit board has a first surface and a second surface corresponding to the first surface, a first circuit layer is disposed on the first surface, a second circuit layer is disposed on the second surface, the first circuit layer comprises plural conductive pads, the second circuit layer comprises a metal contacting pad and a terminal pad, a cavity is formed in the terminal pad and extends to the first circuit layer, a metal layer is disposed in the cavity, an opening is formed in the metal layer, and the metal layer electrically connects to the first circuit layer and the terminal pads. In addition, the semiconductor chip is disposed on the first surface and has plural electrode pads, wherein the electrode pads of the semiconductor chip electrically connect to the conductive pads of the first circuit layer respectively. Furthermore, the conductive element has a plug interlaid into the opening.

In a preferred embodiment of the present invention, the electrical device with the connection interface may selectively comprise: a contacting layer disposed between the plug of the conductive element and the metal layer and/or the first circuit layer. When the electrical device comprises the contacting layer, the plug of the conductive element can be fixed on the circuit board stably, and the problem that the conductive element peels off due to external forces can be prevented. In addition, the electrical device with a connection interface of the present invention may further selectively comprise: an adhesive film disposed between the semiconductor chip and the first surface of the circuit board to fix the semiconductor chip on the circuit board stably. When there are several semiconductor chips laminate to each other, the adhesive film can be disposed between laminated semiconductor chips, so that these laminated semiconductor chips can be fixed to each other.

In the electrical device with the connection interface of the present invention, the conductive element may further selectively comprise a buffer structure. The example of the shape of the buffer structure can be a bend shape, a curve shape, an open-ended parabolic shape, a hyperbolic shape, an irregular embossed shape, and a mushroom shape. The different design of the buffer structure can be applied to various requirements, and also be used as an identification mark.

In a preferred embodiment of the electrical device with the connection interface of the present invention, the metal layer is disposed in the cavity formed in the terminal pad of the circuit board, and the opening penetrates through the metal layer. Hence, the opening extends to the first circuit layer, i.e. the opening exposes the first circuit layer. However, the depth and the shape of the opening are not particularly limited, as long as the plug of the conductive element can be interlaid and be fixed into the opening. Preferably, the shape and the depth of the opening are designed based on those of the plug. It means that the first circuit layer may not be exposed from the opening. In addition, the aforementioned metal contacting pad may be used as a golden finger.

Furthermore, the electrical device with the connection interface of the present invention may selectively comprise: an insulating layer disposed on a surface of the first circuit layer and/or a surface of the second circuit layer, wherein the insulating layer has plural contacting windows to expose at least one of the conductive pads, the metal contacting pad, and the terminal pad. The insulating layer can protect the first circuit layer and the second circuit layer. The contacting windows correspond to the conductive pads, the metal contacting pad, and/or the terminal pad, in order to expose those elements for sequentially electrical connections. For example, the contacting windows can expose the conductive pads, and only the exposed area of the conductive pads is plated for further wire-bonding. By disposing the contacting windows, the area to be plated can be reduced, and thus the manufacturing cost can be further decreased. In another preferred embodiment of the present invention, the insulating layer is disposed on surfaces of both the first circuit layer and the second circuit layer. However, the disposition of the insulating layer is not limited thereto. The insulating layer may also be disposed on a surface of the first circuit layer or a surface of the second circuit layer.

Another object of the present invention is to provide a method for manufacturing an electrical device with a connection interface, wherein an opening is formed on a circuit board. Hence, a conductive element can be interposed on the circuit board directly without using additional mounting terminal modules, so the assembly process can be simplified.

To achieve this object, another aspect of the present invention is to provide a method for manufacturing an electrical device with a connection interface, which comprises the following steps: providing a circuit board with a first surface and a second surface corresponding to the first surface, wherein a first circuit layer is disposed on the first surface, a second circuit layer is disposed on the second surface, the first circuit layer comprises plural conductive pads, the second circuit layer comprises a metal contacting pad and a terminal pad, a cavity is formed in the terminal pad and extends to the first circuit layer, a metal layer is disposed in the cavity, the metal layer electrically connects to the first circuit layer and the terminal pads, and an opening is formed in the metal layer; disposing a semiconductor chip on the first surface of the circuit board, wherein the semiconductor chip has plural electrode pads, and the electrode pads electrically connect to the conductive pads of the first circuit layer respectively; and disposing a conductive element in the opening of the circuit board, wherein the conductive element has a plug, and the plug is interlaid into the opening.

In the method for manufacturing the electrical device with the connection interface of the present invention, the cavity of the circuit board, the opening and the metal layer are formed through a method comprising the following steps: forming a cavity in the terminal pad, wherein the cavity extends to the first circuit layer; depositing a metal in the cavity; and forming an opening in the metal to form a metal layer which covers a surface of an inner wall of the cavity. According to the aforementioned steps, the area for disposing the conductive element on the circuit board is defined by two-steps of hole-forming process, and the conductive element can disposed on the circuit board directly without additional modules.

The method for manufacturing the electrical device with the connection interface of the present invention may further comprise a step of: forming a contacting layer between the plug of the conductive element and the metal layer and/or the first circuit layer. In addition, the method of the present invention may also comprise a step of: forming an adhesive film between the semiconductor chip and the first surface of the circuit board. Herein, the adhesive film may also be used to fix to adjacent semiconductor chips. In addition, the method of the present invention may selectively comprise a step of: forming an insulating layer on a surface of the first circuit layer and/or a surface of the second circuit layer, wherein the insulating layer has plural contacting windows to expose at least one of the conductive pads, the metal contacting pad, and the terminal pad. In a preferred embodiment of the present invention, the step for forming the insulating layer may be performed before the semiconductor is disposed. However, the performing order of this step is not limited thereto, and can be adjust if it is required.

A further object of the present invention is to provide a circuit board for interlaying a conductive element and a method for manufacturing the same, wherein a space for interlaying a conductive element is formed on a circuit board by two-steps of hole-forming process. Hence, the conductive element can be interposed on the circuit board directly without using additional mounting terminal modules, so the assembly process can be simplified.

To achieve this object, another aspect of the present invention is to provide a circuit board for interlaying a conductive element, which comprises: a first surface; a second surface corresponding to the first surface; a first circuit layer disposed on the first surface, wherein the first circuit layer comprises plural conductive pads; and a second circuit layer disposed on the second surface, wherein the second circuit layer comprises a metal contacting pad and a terminal pad, a cavity is formed in the terminal pad and extend to the first circuit layer, a metal layer is disposed on a surface of an inner wall of the cavity, the metal layer electrically connects to the first circuit layer and the terminal pads, and an opening for a conductive element interlaid therein is formed in the metal layer.

A further another aspect of the present invention is to provide a method for manufacturing a circuit board for interlaying a conductive element, which comprises the following steps: providing a circuit board with a first surface and a second surface corresponding to the first surface, wherein a first circuit layer is disposed on the first surface, a second circuit layer is disposed on the second surface, the first circuit layer comprises plural conductive pads, and the second circuit layer comprises a metal contacting pad and a terminal pad; forming a cavity in the terminal pad of the circuit board, wherein the cavity extends to the first circuit layer; depositing a metal in the cavity; and forming an opening in the metal to form a metal layer which covers a surface of an inner wall of the cavity, wherein the opening is used for a conductive element interlaid therein.

The aforementioned connection interface can be applied to various specifications such as peripheral component interconnection bus (PCI), industry standard architecture (ISA), Universal Serial Bus (USB) or equivalent connection interfaces. Preferably, the aforementioned connection interface is applied to USB 3.0.

According to the present invention, a space for interlaying a conductive element can be defined on a circuit board. Hence, the conductive element can be mounted in this space without using additional mounting terminal modules, and thus the assembly process can be further simplified.

Other objects, advantages, and novel features of the invention will become more apparent from the following detailed description when taken in conjunction with the accompanying drawings.

### BRIEF DESCRIPTION OF THE DRAWINGS

FIG. 1A to FIG. 1D are perspective views showing a process for manufacturing a circuit board for interlaying a conductive element according to Embodiment 1 of the present invention;

FIG. 1D to FIG. 1I are perspective views showing a process for manufacturing an electrical device with a connection interface according to Embodiment 2 of the present invention;

FIG. 2 is a perspective view of an electrical device with a connection interface according to Embodiment 3 of the present invention;

FIG. 3 is a perspective view of an electrical device with a connection interface according to Embodiment 4 of the present invention;

FIG. 4 is a perspective view of an electrical device with a connection interface according to Embodiment 5 of the present invention;

FIG. 5 is a perspective view of an electrical device with a connection interface according to Embodiment 6 of the present invention; and

FIG. 6 is a perspective view of an electrical device with a connection interface according to Embodiment 7 of the present invention.

### DETAILED DESCRIPTION OF THE PREFERRED EMBODIMENT

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

In the following embodiments of the present invention, the figures are simplified perspective views. However, only the elements relate to the present invention are shown in these figures. These shown embodiments are not actual performance aspects. The numbers, the shapes and the sizes of the shown elements are only one selective design, and they may be more complicated.

### Embodiment 1

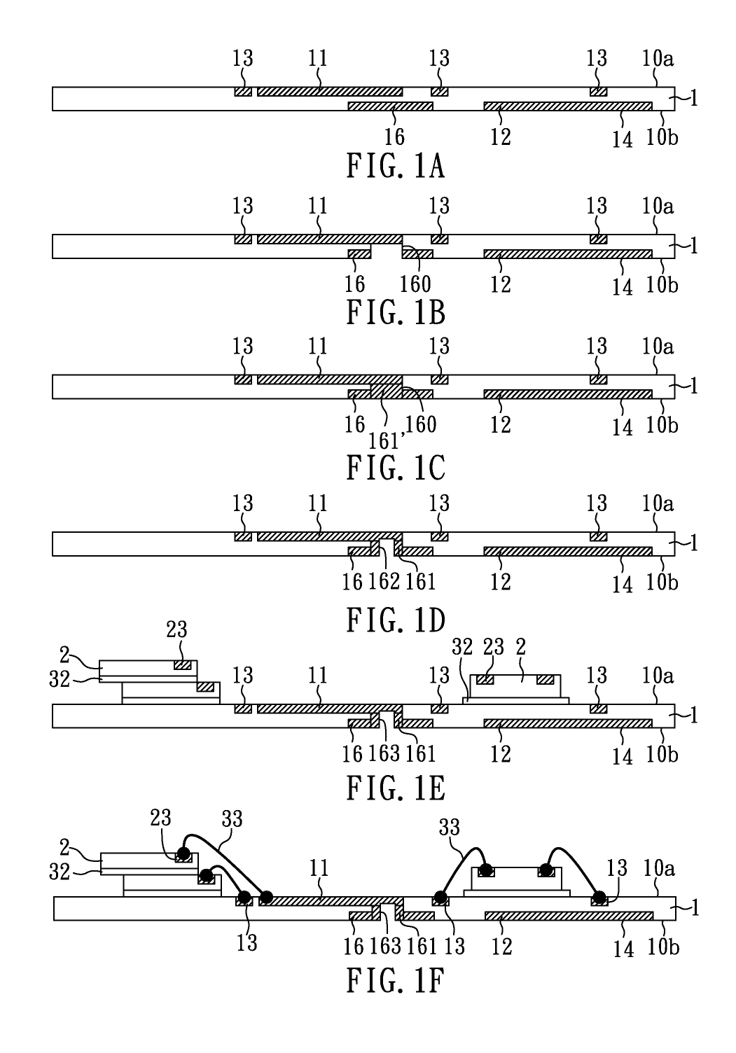

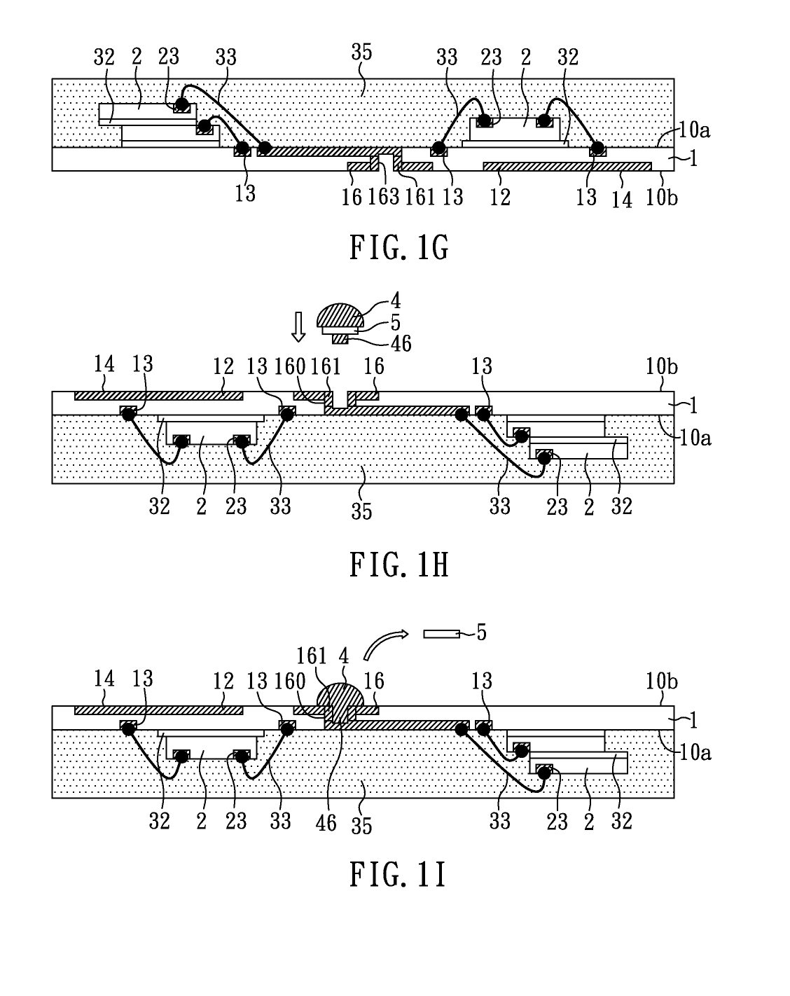

FIG. 1A to FIG. 1D are perspective views showing a process for manufacturing a circuit board for interlaying a conductive element of the present embodiment.

As shown in FIG. 1A, a circuit board 1 is provided. The circuit board 1 has a first surface 10a and a second surface 10b corresponding to the first surface 10a. A first circuit layer 11 is disposed on the first surface 10a, a second circuit layer 12 is disposed on the second surface 10b, the first circuit layer 11 comprises plural conductive pads 13, and the second circuit layer 12 comprises a metal contacting pad 14 and a terminal pad 16. The method for manufacturing the circuit board 1 is not particularly limited, and any conventional method known in the art can be used in the present embodiment. For example, the circuit board 1 can be formed by using a substrate with two Cu films formed on two surface of the substrate, and followed by patterning the Cu films with a lithography process to form the first circuit layer 11 and the second circuit layer 12.

Next, as shown in FIG. 1B, a cavity 160 is formed in the terminal pad 16 of the circuit board 1, wherein the cavity 160 extends to the first circuit layer 11. The method for forming the cavity 160 is not particularly limited. For example, the cavity 160 can be formed by a laser drilling process.

As shown in FIG. 1C, a metal 161′ is deposited in the cavity 160. In this step, other portions or elements except for the region exposed from the cavity 160 can be protected by a resisting layer, and then an electroless plating process or an electroplating process is performed to form the metal 161′ in the cavity 160.

Then, as shown in FIG. 1D, an opening 162 is formed in the metal 161′ to form a metal layer 161, which covers a surface of an inner wall of the cavity 160. Herein, the opening 162 is used for a conductive element (not shown in the figure) interlaid therein. In the process for forming the opening 162, other portions or elements except for the region for forming the opening 162 can be protected by a resisting layer, and then an etching process is performed on the region which is not protected by the resisting layer to form the opening 162. Alternatively, the opening 162 may also be formed with a laser drilling process.

After the aforementioned process, the present embodiment provides a circuit board for interlaying a conductive element, which comprises: a first surface 10a; a second surface 10b corresponding to the first surface 10a; a first circuit layer 11 disposed on the first surface 10a, wherein the first circuit layer 11 comprises plural conductive pads 13; and a second circuit layer 12 disposed on the second surface 10b, wherein the second circuit layer 12 comprises a metal contacting pad 14 and a terminal pad 16, a cavity 160 is formed in the terminal pad 16 and extend to the first circuit layer 11, a metal layer 161 is disposed on a surface of an inner wall of the cavity 160, the metal layer 161 electrically connects to the first circuit layer 11 and the terminal pads 16, and an opening 162 for a conductive element interlaid therein is formed in the metal layer 161.

### Embodiment 2

FIG. 1D to FIG. 1I are perspective views showing a process for manufacturing an electrical device with a connection interface of the present embodiment.

As shown in FIG. 1D, a circuit board 1 is provided. The circuit board 1 has a first surface 10a and a second surface 10b corresponding to the first surface 10a. A first circuit layer 11 is disposed on the first surface 10a, a second circuit layer 12 is disposed on the second surface 10b, the first circuit layer 11 comprises plural conductive pads 13, the second circuit layer 12 comprises a metal contacting pad 14 and a terminal pad 16, a cavity 160 is formed in the terminal pad 16 and extends to the first circuit layer 11, a metal layer 161 is disposed in the cavity 160, the metal layer 161 electrically connects to the first circuit layer 11 and the terminal pads 16, and an opening 162 is formed in the metal layer 161.

Next, as shown in FIG. 1E, adhesive films 32 are formed between the semiconductor chips 2 and the first surface 10a of the circuit board 1 to mount the semiconductor chips 2 on the first surface 10a of the circuit board 1. Herein the semiconductor chips 2 have plural electrode pads 23. Then, as shown in FIG. 1F, the electrode pads 23 electrically connect to the conductive pads 13 of the first circuit layer 11 respectively via wire bonds 33. A molding process is performed to form a molding layer 35 to protect the semiconductor chips 2, as shown in FIG. 1G. The example of the material of the molding layer 35 can be epoxy resin.

As shown in FIG. 1H and FIG. 1I, a conductive element holder 5 is used to carry a conductive element 4 with a plug 46. The conductive element holder 5 can align the plug 46 of the conductive element 4 with the opening 162 of the circuit board 1, and then the plug 46 can be interlaid into the opening 162 exactly. Herein, the conductive element holder 5 may carry plural conductive elements 4, so plural conductive elements 4 can be interlaid into plural openings 162 of the circuit board 1 at the same time, when there are two or more opening 162 formed on the circuit board 1. According to the aforementioned illustration, it can be understand that the relation between the conductive element 4 and the opening 162 is like the relation between a bolt and a bolt hole.

After the aforementioned process, the present embodiment provides an electrical device with a connection interface, which comprises: a circuit board 1 with a first surface 10a and a second surface 10b corresponding to the first surface 10a, wherein a first circuit layer 11 is disposed on the first surface 10a, a second circuit layer 12 is disposed on the second surface 10b, the first circuit layer 11 comprises plural conductive pads 13, the second circuit layer 12 comprises a metal contacting pad 14 and a terminal pad 16, a cavity 160 is formed in the terminal pad 16 and extends to the first circuit layer 11, a metal layer 161 is disposed in the cavity 160, an opening 162 is formed in the metal layer 161, and the metal layer 161 electrically connects to the first circuit layer 11 and the terminal pads 16; a semiconductor chip 2 disposed on the first surface 10a and having plural electrode pads 23, wherein the electrode pads 23 of the semiconductor chip 2 electrically connect to the conductive pads 13 of the first circuit layer 11 respectively; a conductive element 4 with a plug 46 interlaid into the opening 162; and an adhesive film 32 disposed between the semiconductor chip 2 and the first surface 10a of the circuit board 1.

### Embodiments 3-7

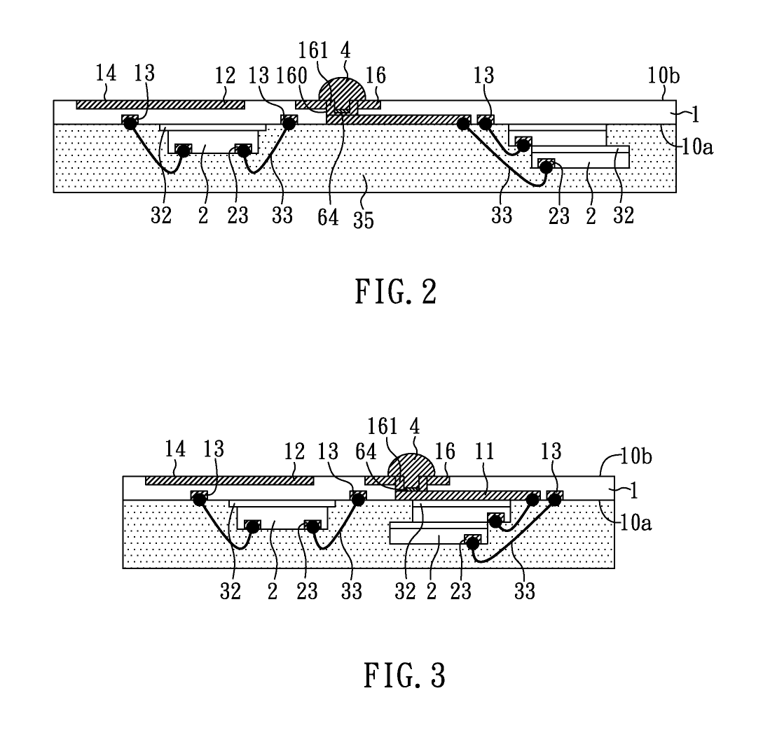

FIG. 2 to FIG. 6 are perspective views of an electrical device with a connection interface of Embodiments to Embodiment 7 respectively.

As shown in FIG. 2, the structure of the electrical device with a connection interface of Embodiment 3 is similar to that of Embodiment 2, except that the bottom of the plug 46 of the conductive element 4 is firstly coated with a contacting layer 64, and then the plug 46 of the conductive elements 4 is aligned with and interlaid into the opening 162 of the circuit board 1. In addition, the opening 162 of the circuit board 1 does not extend to the first circuit layer 11, i.e. the first circuit layer 11 is not exposed from the opening 162. Hence, compared to the electrical device with a connection interface of Embodiment 2, the electrical device with a connection interface of Embodiment 3 further comprises a contacting layer 64, which is disposed between the plug 46 of the conductive element 4 and the metal layer 161.

As shown in FIG. 3, the structure of the electrical device with a connection interface of Embodiment 4 is similar to that of Embodiment 3, except that the opening 162 of the circuit board 1 extends to the first circuit layer 11, i.e. the first circuit layer 11 is exposed from the opening 162. Hence, the contacting layer 64 is disposed between the plug 46 of the conductive element 4 and the first circuit layer 11. In addition, a semiconductor chip 2 is disposed on a surface of the first circuit layer 11, but not on the region that no circuit is formed thereon.

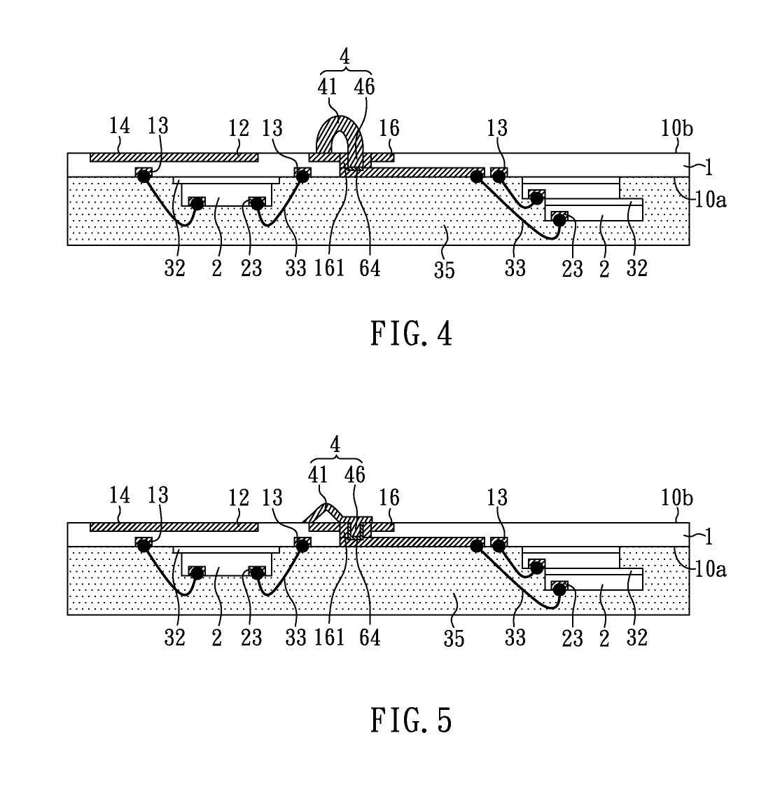

As shown in FIG. 4, the structure of the electrical device with a connection interface of Embodiment 5 is similar to that of Embodiment 2, except that the opening 162 of the circuit board 1 extends to the first circuit layer 11, i.e. the first circuit layer 11 is exposed from the opening 162. Hence, the contacting layer 64 is disposed between the plug 46 of the conductive element 4 and the first circuit layer 11. In addition, the conductive element 4 comprises a curved buffer structure 41 to absorb pressure or stress of pressing.

As shown in FIG. 5, the structure of the electrical device with a connection interface of Embodiment 6 is similar to that of Embodiment 5, except that the contacting layer 64 is disposed between the plug 46 of the conductive element 4 and the first circuit layer 11 and the metal layer 161. In addition, the conductive element 4 also comprises a bent buffer structure 41 to absorb pressure or stress of pressing.

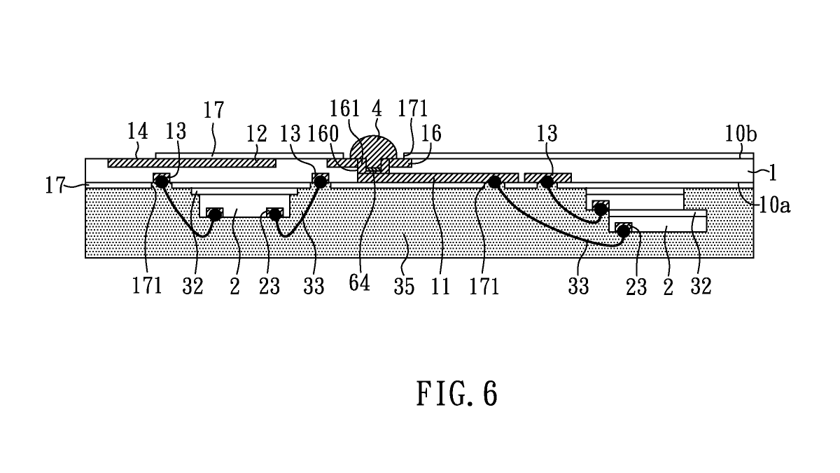

As shown in FIG. 6, the structure of the electrical device with a connection interface of Embodiment 7 is similar to that of Embodiment 3, except that an insulating layer 17 is formed on the first surface 10a and the second surface 10b of the circuit board 1 before the semiconductor chip 2 is disposed thereon. The insulating layer 17 covers the first circuit layer 11 and the second circuit layer 12. In addition, the insulating layer 17 has plural contacting windows 171 to expose the conductive pads 13, the metal contacting pad 14 and the terminal pad 16.

Although the present invention has been explained in relation to its preferred embodiment, it is to be understood that many other possible modifications and variations can be made without departing from the spirit and scope of the invention as hereinafter claimed.

What is claimed is:

1. An electrical device with a connection interface, comprising:
a circuit board with a first surface and a second surface corresponding to the first surface, wherein a first circuit layer is disposed on the first surface, a second circuit layer is disposed on the second surface, the first circuit layer comprises plural conductive pads, the second circuit layer comprises a metal contacting pad and a terminal pad, a cavity is formed in the terminal pad and extends to the first circuit layer, a metal layer is disposed in the cavity, an opening is formed in the metal layer, and the metal layer electrically connects to the first circuit layer and the terminal pads;
a semiconductor chip disposed on the first surface and having plural electrode pads, wherein the electrode pads of the semiconductor chip electrically connect to the conductive pads of the first circuit layer respectively; and
a conductive element with a plug interlaid into the opening.

2. The electrical device with the connection interface as claimed in claim 1, further comprising: a contacting layer disposed between the plug of the conductive element and the metal layer and/or the first circuit layer.

3. The electrical device with the connection interface as claimed in claim 2, further comprising: an adhesive film disposed between the semiconductor chip and the first surface of the circuit board.

4. The electrical device with the connection interface as claimed in claim 3, wherein the conductive element further comprises a buffer structure.

5. The electrical device with the connection interface as claimed in claim 1, wherein the opening penetrates through the metal layer.

6. The electrical device with the connection interface as claimed in claim 1, further comprising: an insulating layer disposed on a surface of the first circuit layer and/or a surface of the second circuit layer, wherein the insulating layer has plural contacting windows to expose at least one of the conductive pads, the metal contacting pad, and the terminal pad.

7. A method for manufacturing an electrical device with a connection interface, comprising the following steps:
providing a circuit board with a first surface and a second surface corresponding to the first surface, wherein a first circuit layer is disposed on the first surface, a second circuit layer is disposed on the second surface, the first circuit layer comprises plural conductive pads, the second circuit layer comprises a metal contacting pad and a terminal pad, a cavity is formed in the terminal pad and extends to the first circuit layer, a metal layer is disposed in the cavity, the metal layer electrically connects to the first circuit layer and the terminal pads, and an opening is formed in the metal layer;
disposing a semiconductor chip on the first surface of the circuit board, wherein the semiconductor chip has plural electrode pads, and the electrode pads electrically connect to the conductive pads of the first circuit layer respectively; and
disposing a conductive element in the opening of the circuit board, wherein the conductive element has a plug, and the plug is interlaid into the opening.

8. The method for manufacturing an electrical device with a connection interface as claimed in claim 7, wherein the cavity of the circuit board, the opening and the metal layer are formed through a method comprising the following steps:
forming a cavity in the terminal pad, wherein the cavity extends to the first circuit layer;
depositing a metal in the cavity; and
forming an opening in the metal to form a metal layer which covers a surface of an inner wall of the cavity.

9. The method for manufacturing the electrical device with the connection interface as claimed in claim 8, further comprising a step of:
forming a contacting layer between the plug of the conductive element and the metal layer and/or the first circuit layer.

10. The method for manufacturing the electrical device with the connection interface as claimed in claim 9, further comprising a step of:
forming an adhesive film between the semiconductor chip and the first surface of the circuit board.

11. The method for manufacturing the electrical device with the connection interface as claimed in claim 10, wherein the conductive element further comprises a buffer structure.

12. The method for manufacturing the electrical device with the connection interface as claimed in claim 7, wherein the opening penetrates through the metal layer.

13. The method for manufacturing the electrical device with the connection interface as claimed in claim 7, further comprising a step of: forming an insulating layer on a surface of the first circuit layer and/or a surface of the second circuit layer, wherein the insulating layer has plural contacting windows to expose at least one of the conductive pads, the metal contacting pad, and the terminal pad.

14. A circuit board for interlaying a conductive element, comprising:
a first surface;
a second surface corresponding to the first surface;
a first circuit layer disposed on the first surface, wherein the first circuit layer comprises plural conductive pads; and
a second circuit layer disposed on the second surface, wherein the second circuit layer comprises a metal contacting pad and a terminal pad, a cavity is formed in the terminal pad and extend to the first circuit layer, a metal layer is disposed on a surface of an inner wall of the cavity, the metal layer electrically connects to the first circuit layer and the terminal pads, and an opening for a conductive element interlaid therein is formed in the metal layer.

15. A method for manufacturing a circuit board for interlaying a conductive element, comprising the following steps:
providing a circuit board with a first surface and a second surface corresponding to the first surface, wherein a first circuit layer is disposed on the first surface, a second circuit layer is disposed on the second surface, the first circuit layer comprises plural conductive pads, and the second circuit layer comprises a metal contacting pad and a terminal pad;
forming a cavity in the terminal pad of the circuit board, wherein the cavity extends to the first circuit layer;
depositing a metal in the cavity; and
forming an opening in the metal to form a metal layer which covers a surface of an inner wall of the cavity, wherein the opening is used for a conductive element interlaid therein.
